(19) United States
(12) Patent Application Publication
(10) Pub. No.: US 2013/0077256 A1
(43) Pub. Date: Mar. 28, 2013

(54) HEAT DISSIPATION STRUCTURE FOR ELECTRONIC DEVICE

(71) Applicant: Tatsuro Kuroda, Osaka (JP)

(72) Inventor: Tatsuro Kuroda, Osaka (JP)

(73) Assignee: SHARP KABUSHIKI KAISHA, Osaka (JP)

(21) Appl. No.: 13/702,408

(22) PCT Filed: May 24, 2011
(86) PCT No.: PCT/JP2011/061818

§ 371 Date: Dec. 6, 2012

(30) Foreign Application Priority Data
Jun. 9, 2010 (JP) 2010-131934

(51) Int. Cl. H05K 7/20

(52) U.S. Cl. CPC H05K 7/2039
USPC 361/719

(57) ABSTRACT

Disclosed is a heat dissipation structure of dissipating heat through a heat dissipation sheet disposed between a cover member and an IC chip, which is a heat-generating element, mounted on a substrate. Specifically disclosed is a heat dissipation structure of an electronic device that can ensure that the heat dissipation sheet is reliably disposed between the IC chip and the cover member without falling off upon being attached to the IC chip and that dissipates heat sufficiently, thereby improving reliability of the electronic device. In order to achieve this heat dissipation structure, a heat dissipation sheet (1) is provided with, on a bottom surface (11) that corresponds to a contact surface with the IC chip 3, a heat transfer surface (11B) that comes in contact with the heat-generating section of the IC chip and that has no adhesive applied thereon and a bonding surface (11A) that comes in contact with an area other than the heat-generating section and that has an adhesive applied thereon.

### TECHNICAL FIELD

The present invention relates to a heat dissipation structure of an electronic device used for a liquid crystal display device and the like.

### BACKGROUND ART

In recent years, electronic devices that are provided with substrates having electronic components such as IC chips (semiconductor chips) mounted thereon have been widely available. On substrates for driving liquid crystal display panels of liquid crystal display devices, for example, large numbers of such electronic components are mounted.

The density of the electronic components that are used in various electronic devices has been increased in order to respond to sizes of the electronic devices being reduced. Arranging the electronic components such as IC chips densely in a small space results in a serious heat problem that requires a measure to dissipate heat.

The electronic components such as IC chips mounted on the substrate undergo change in characteristics due to increase in temperature caused by heat generation upon using the electronic device. This may cause device malfunction and electronic component failure. Therefore, a heat dissipation structure for suppressing an increase in temperature of the electronic components such as IC chips has been conventionally proposed.

A heat dissipation structure of using a heat dissipation plate for dissipating heat generated in the electronic components such as IC chips has been proposed, for example. Also, a heat dissipation structure of having a rubber sheet with heat conductivity disposed between a heat dissipation plate and IC chips and immediately transmitting heat from the IC chips to the heat dissipation plate through the rubber sheet has been proposed.

In case of having a plurality of IC chips mounted on the same substrate, a plurality of heat-generating elements are disposed close to each other. For electronic devices having such a configuration, it is required to dissipate heat from each of the IC chips even more rapidly.

However, when the heights of the respective mounted chips vary, which is caused by varied thicknesses thereof, a heat dissipation structure suited to each of the IC chips needs to be employed by placing rubber sheets or heat dissipation plates corresponding to the respective IC chips that have various heights.

For this purpose, heat dissipation sheets are directly disposed on the respective IC chips to dissipate heat from the respective IC chips. For example, a heat dissipation structure of an electronic device described as follows has been already proposed. In this heat dissipation structure of the electronic device, a silicon rubber sheet for heat dissipation is disposed between heat-generating elements mounted on a substrate and a metal case; heat from the heat-generating elements is transmitted immediately to the metal case; and the heat is dissipated outside of the device (see Patent Document 1, for example).

In a liquid crystal display device having a backlight that uses an LED (light-emitting diode) as a light source, LED chips themselves become heat-generating elements. Therefore, it is preferable that heat generated from the LED chips be immediately dissipated. To this end, a liquid crystal display device described as follows has been already proposed. In this liquid crystal display device, a metal case having an excellent heat dissipation characteristic is positioned using a fitting member and is attached such that heat generated from the LED chips is efficiently dissipated (see Patent Document 2, for example).

### RELATED ART DOCUMENTS

### Patent Documents

Patent Document 1: Japanese Patent Application Laid-Open Publication No. H10-308484
Patent Document 2: Japanese Patent Application Laid-Open Publication No. 2010-2745

### SUMMARY OF THE INVENTION

### Problems to be Solved by the Invention

Heat generated in heat-generating elements such as IC chips can be dissipated from a cover member by disposing a heat dissipation sheet having excellent heat conductivity, such as a silicon rubber sheet, between the heat-generating elements such as IC chips mounted on a substrate and the cover member that covers the substrate and that serves as a heat dissipation plate. Also, if the heat dissipation sheet to be used is soft, this heat dissipation sheet can address size variation of gaps between the respective heat-generating elements such as the IC chips and the cover member to some extent.

However, when mounting a plurality of IC chips having various heights on the same substrate, sizes of respective gaps between the respective IC chips and a substrate cover vary. Consequently, contact pressures between the respective IC chips and the heat dissipation sheet vary, which results in a problem of decreased heat dissipation performance. Therefore, it is preferable that the heat dissipation sheet having an appropriate thickness suited for the gap sizes be disposed.

By providing chip pressing members that have heat conductivity and that are made of protrusions formed on a substrate cover, heat dissipation sheets that have a uniform thickness may be disposed. In this case, it is necessary to form the chip pressing members in advance to have prescribed protrusion heights corresponding to the respective thicknesses of the chips that are mounted. However, if a dimension error occurs upon fabrication, the protrusion height becomes different from the prescribed height. This leads to a problem of having too small or too large contact pressure.

If the heat dissipation sheets respectively attached to the plurality of IC chips are displaced or fallen off upon placing a heat dissipation plate and a cover member on the heat dissipation sheets, heat would not be dissipated sufficiently, thereby increasing a temperature in the IC chips. This leads to a change in characteristics of the IC chips, causing problems such as device malfunction and electronic component failure.

If the contact pressure between the heat dissipation sheets and the IC chips is small, or if the heat dissipation sheets fall off from the IC chips due to contact pressure being too small, heat dissipation performance is degraded, resulting in a problem. On the other hand, if the contact pressure is too high, the substrate is bent and damaged or the IC chips are damaged, resulting in a problem.

In order to avoid such problems, it is preferable that the heat dissipation structure be configured such that, even if the heights of the plurality of the respective IC chips mounted on the substrate vary, the heat dissipation sheets do not fall off upon being attached to the IC chips, and reliably come in contact with the entire surfaces of the respective IC chips with an appropriate contact pressure, thereby reliably dissipating heat.

The present invention was made in view of the above problems, and aims at providing a heat dissipation structure of an electronic device that includes IC chips, i.e., heat-generating elements, mounted on a substrate, and heat dissipation sheets respectively interposed between the IC chips and a cover member for heat dissipation and that can allow the heat dissipation sheets to be reliably disposed between the IC chips and the cover member without falling off upon being attached to the IC chips, thereby achieving a sufficient heat dissipation and an improvement in reliability of the electronic device.

### Means for Solving the Problems

In order to achieve the above object, in the present invention, a heat dissipation structure of an electronic device is provided with: an IC chip; a substrate having the IC chip mounted thereon; a cover member having a heat dissipation characteristic and covering a mounting surface of the substrate; and a heat dissipation sheet disposed between the IC chip and the cover member, the heat dissipation structure dissipating heat in the IC chip, wherein the heat dissipation sheet has, on a bottom surface that corresponds to a contact surface with the IC chip, a heat transfer surface that comes in contact with a heat-generating section of the IC chip and that has no adhesive applied thereon and a bonding surface that comes in contact with an area other than the heat-generating section and that has an adhesive applied thereon.

According to this configuration, the heat dissipation sheet is reliably bonded to the IC chip by the bonding surface having the adhesive applied thereon, and therefore, the heat dissipation sheet does not easily fall off the IC chip. In addition, heat is dissipated sufficiently through the heat transfer surface having no adhesive applied thereon. Therefore, the heat dissipation structure of the electronic device that can improve reliability of the electronic device can be achieved.

In the above heat dissipation structure of the electronic device of the present invention, a recessed engaging section that engages the IC chip may be provided in the bottom surface, a recessed surface of the recessed engaging section is used as the heat transfer surface that comes in contact with the IC chip, and a surface surrounding the recessed engaging section in the bottom surface is used as the bonding surface. With this configuration, the bonding surface is bonded to the substrate having the IC chip mounted thereon. Therefore, it is possible to reliably fix and bond the heat dissipation sheet in an area other than the heat-generating section. Further, heat is dissipated sufficiently through the heat transfer surface that comes in contact with the IC chip.

In the above heat dissipation structure of the electronic device of the present invention, a top surface of the heat dissipation sheet facing the bottom surface may have corners cut in a tapered shape. According to this configuration, the corners of the top surface of the heat dissipation sheet to be bonded to the IC chip have a tapered shape. This makes it difficult for the heat dissipation sheet to fall off upon being attached to the IC chip. Therefore, it becomes possible to reliably attach the heat dissipation sheet to the IC chip.

In the above heat dissipation structure of the electronic device of the present invention, the top surface of the heat dissipation sheet facing the bottom surface may have corners rounded in a circular arc shape. With this configuration, the corners of the top surface of the heat dissipation sheet to be bonded to the IC chip are rounded in a circular arc shape. This makes it difficult for the heat dissipation sheet to fall off upon being attached to the IC chip. Therefore, it becomes possible to reliably attach the heat dissipation sheet to the IC chip.

In the above heat dissipation structure of the electronic device of the present invention, the heat dissipation sheet may be formed in a flattened shape having rounded side surfaces between the bottom surface and the top surface facing the contact surface. With this configuration, the side surfaces of the heat dissipation sheet to be bonded to the IC chip are rounded. This makes it difficult for the heat dissipation sheet to fall off upon being attached to the IC chip. Therefore, it becomes possible to reliably attach the heat dissipation sheet to the IC chip.

In the above heat dissipation structure of the electronic device of the present invention, the heat dissipation sheet may have particulate heat-conducting additive having heat conductivity mixed therein. With this configuration, even if the heat dissipation sheet is made thick, heat conductivity is ensured in a thickness direction. Therefore, heat in the IC chip can be reliably dissipated.

In the above heat dissipation structure of the electronic device of the present invention, the heat dissipation sheet may have a film member that has heat conductivity and that is made of nonconductors disposed on at least one of the bottom surface and the top surface. With this configuration, even if the heat-conducting additive to be mixed in the heat dissipation sheet is electrically conductive, it becomes possible to prevent unintended electrical conduction in the IC chip.

In the above heat dissipation structure of the electronic device of the present invention, the heat-conducting additive may be metal particles. With this configuration, heat in the IC chip is reliably dissipated through the heat dissipation sheet that has metal particles with high heat conductivity mixed therein. This way, heat is dissipated sufficiently, and reliability of the electronic device can be therefore improved.

In the above heat dissipation structure of the electronic device of the present invention, the heat dissipation sheet may have a heat-conducting auxiliary layer having heat conductivity interposed therein. With this configuration, heat in the IC chip is reliably dissipated through the heat-conducting auxiliary layer having high heat conductivity. This way, heat is dissipated sufficiently, and reliability of the electronic device can be therefore improved.

In the above heat dissipation structure of the electronic device of the present invention, the heat transfer surface in the recessed engaging section may be a protruded heat transfer surface having a center thereof protruded in a curved shape. With this configuration, the heat transfer surface is protruded in a curved shape. This way, the heat dissipation sheet reliably comes in contact with the center of the IC chip, which is the heat-generating section. Therefore, heat is dissipated sufficiently, and reliability of the electronic device can be therefore improved.

In the above heat dissipation structure of the electronic device of the present invention, the recessed engaging section may have a center engaging section that engages an outer shape of the IC chip and a terminal contact surface that comes in contact with an electrode terminal, which is provided on a side face of the IC chip. With this configuration, the heat dissipation sheet also comes in contact with the electrode terminal, and heat in the electrode terminal can be also dissipated. Therefore, heat in the IC chip can be dissipated more effectively.

In the above heat dissipation structure of the electronic device of the present invention, the center engaging section may have a clearance section in a circumference thereof. With this configuration, it is possible to prevent the circumference of the center engaging section formed in the heat dissipation sheet from coming in contact with the IC chip first, which would prevent the heat transfer surface from coming in contact with the heat-generating section in the center of the IC chip. This way, the heat transfer surface of the heat dissipation sheet reliably comes in contact with the heat-generating section of the IC chip. Therefore, heat is dissipated sufficiently, and reliability of the electronic device can be therefore improved.

In the above heat dissipation structure of the electronic device of the present invention, the terminal contact surface may be a protruded terminal contact surface that is protruded toward the electrode terminal. With this configuration, the terminal contact surface on the heat dissipation sheet reliably comes in contact with the electrode terminal, and therefore, heat can be dissipated.

### Effects of the Invention

According to the present invention, in the heat dissipation structure in which an IC chip that becomes a heat-generating element, is mounted on s substrate, and a heat dissipation sheet is disposed between a cover member and the IC chip so as to dissipate heat, the heat dissipation sheet has, on the bottom surface that corresponds to a contact surface with the IC chip, the heat transfer surface and the bonding surface. The heat transfer surface comes in contact with a heat-generating section of the IC chip and has no adhesive applied thereon. The bonding surface comes in contact with an area other than the heat-generating section of the IC chip and has an adhesive applied thereon. This way, the heat dissipation sheet reliably comes in contact with the IC chip by the bonding surface having the adhesive, and therefore, the heat dissipation sheet does not fall off easily. Further, heat is dissipated sufficiently through the heat transfer surface having no adhesive. Therefore, it becomes possible to achieve the heat dissipation structure of the electronic device that can improve reliability of the electronic device.

### BRIEF DESCRIPTION OF THE DRAWINGS

FIG. 1A is a schematic side view showing a heat dissipation structure of an electronic device according to the present invention.

FIG. 1B is a schematic plan view showing the heat dissipation structure of the electronic device according to the present invention.

FIG. 2A is a schematic perspective view showing an example of a heat dissipation sheet according to the present invention.

FIG. 2B is a schematic cross-sectional view showing an example of the heat dissipation sheet according to the present invention.

FIG. 3A is a side view of the heat dissipation sheet according to the present invention. More particularly, FIG. 3A is a side view of a heat dissipation sheet in Embodiment 1 having tapered corners.

FIG. 3B is a side view of a heat dissipation sheet in Embodiment 2 having rounded corners.

FIG. 3C is a side view of a heat dissipation sheet in Embodiment 3 having a flattened shape.

FIG. 4A is a cross-sectional view showing another example of a heat dissipation sheet having a heat-conducting additive is mixed therein.

FIG. 4B is a cross-sectional view showing an example of a heat dissipation sheet provided with a film member made of a nonconductive material.

FIG. 4C is a cross-sectional view showing an example of a heat dissipation sheet having heat-conducting auxiliary layers interposed therein.

FIG. 5A is an enlarged view showing a principal portion of an elastic pressing member, which is a modification example of a substrate pressing member.

FIG. 5B is a diagram showing an attachment example of the elastic pressing member shown in FIG. 5A.

FIG. 6A is a cross-sectional view showing a heat dissipation sheet in another embodiment that is provided with a recessed engaging section.

FIG. 6B is a cross-sectional view showing a heat dissipation sheet in another embodiment that is provided with a protruded heat transfer surface on the recessed engaging section.

FIG. 7A is a cross-sectional view showing a heat dissipation sheet in a modification example that is provided with a recessed engaging section and a terminal contact surface.

FIG. 7B is a cross-sectional view showing a modification example of the heat dissipation sheet shown in FIG. 7A that is further provided with a protruded heat transfer surface.

FIG. 7C is a cross-sectional view showing a modification example in which a clearance section is formed in a circumference of a center engaging section.

FIG. 7D is a cross-sectional view showing a modification example in which a tapered-shape protruded terminal contact surface is provided.

FIG. 7E is a cross-sectional view showing a modification example in which a protruded terminal contact surface protruded in a curved shape is provided.

### DETAILED DESCRIPTION OF EMBODIMENTS

Embodiments of the present invention will be described below with reference to figures. The same components are given the same reference characters, and a detailed description thereof is omitted where appropriate.

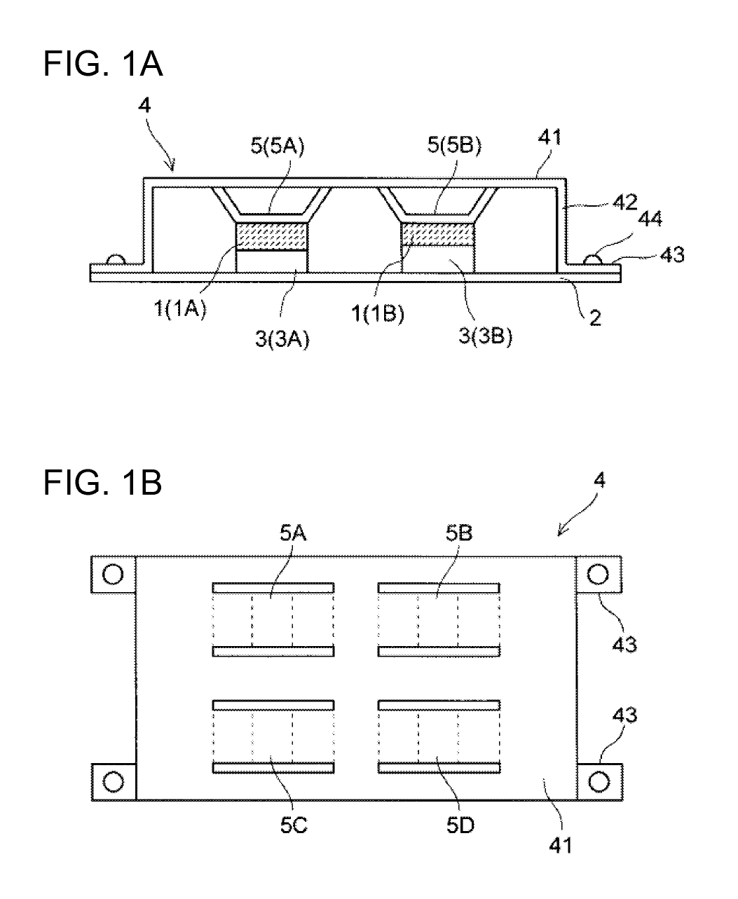

A heat dissipation structure of an electronic device according to this embodiment is a heat dissipation structure for an electronic device provided with a substrate having electronic components such as IC chips (semiconductor chips) mounted thereon. As shown in FIG. 1A, for example, the heat dissipation structure dissipates heat through heat dissipation sheets 1 (1A and 1B) that are disposed between IC chips 3 (3A and 3B) mounted on a substrate 2 and a cover member 4 such as a substrate cover.

It is preferable that the heat dissipation sheet be a rubber sheet that is soft enough to be easily deformed in a thickness direction and that has a rubber hardness that allows the heat dissipation sheet to be easily pressed against and reliably come in contact with the IC chips 3, regardless of size variation in respective gaps between the respective IC chips 3 and the cover member 4. A rubber sheet that has a heat dissipation characteristic such as a silicon rubber sheet or an acrylic rubber sheet and that has an Asker C hardness of about 10 to 60, for example, can be used for the heat dissipation sheet. The Asker C hardness is a standard measurement of a rubber hardness defined by the Society of Rubber Science and Technology, Japan, and corresponds to the Shore hardness E defined by JIS K 6253.

The cover member 4 is a substrate cover having a top surface 41, a side surface 42, and a mounting surface 43. The cover member 4 is made of a metal plate such as an aluminum plate having heat conductivity and being capable of dissipating heat. This metal plate is bent such that the mounting surface 43 is placed on the substrate 2, and the metal plate is screwed and fixed to the substrate 2 using a set screw 44. If the plurality of IC chips 3 (3A and 3B) are to be mounted on the substrate 2, chip pressing members 5 (5A and 5B) are provided on the top surface in areas corresponding to the areas where the IC chips are mounted.

As shown in FIG. 1B, if four IC chips 3 are mounted on the rectangular substrate 2, for example, the cover member 4 is also formed in a rectangular shape in a plan view. Further, corresponding to the number of the IC chips 3 mounted on the substrate 2, four chip pressing members 5 (5A, 5B, 5C, and 5D) are provided on the cover member 4 having a rectangular shape in a plan view. It is preferable that these chip pressing members 5 (5A to 5D) be also made of a metal plate having heat conductivity. These chip pressing members 5 can be made of portions of the top surface 41 of the cover member 4 having heat conductivity by a sheet metal processing technique. Alternatively, the chip pressing members may be made of other materials having heat conductivity and may be bonded to the cover member 4, but there is no special limitation.

The respective chip pressing members 5 are formed to protrude to respective prescribed heights that allow the heat dissipation sheets 1 to be held by pressure between the respective IC chips 3 and the cover member 4. It is preferable that the heat dissipation sheets 1 be soft sheets made of silicon rubber or acrylic rubber having an excellent heat dissipation characteristic. This makes it easier to elastically press the heat dissipation sheets 1 by the chip pressing members 5, such that the heat dissipation sheets 1 are pressed on and come in contact with the IC chips 3.

With this configuration, heat in the IC chips 3 is immediately transmitted from the heat dissipation sheets 1 having heat conductivity through the chip pressing members 5 to the cover member 4 that doubles as a heat dissipation plate. Therefore, the heat in the IC chips 3 can be immediately dissipated.

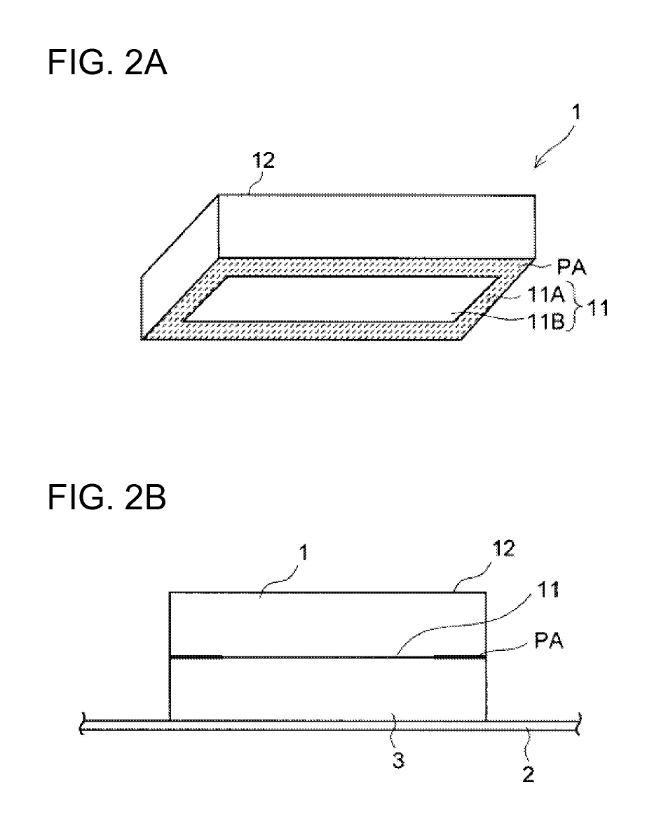

Next, a configuration of the heat dissipation sheet 1 that can be reliably disposed between the IC chip and the cover member without falling off upon being attached to the IC chip and that dissipates heat sufficiently will be described with reference to FIGS. 2A and 2B.

As shown in a perspective view in FIG. 2A, the heat dissipation sheet 1 to be attached to the IC chip is rectangular and has a bottom surface 11, which is a contact surface with the IC chip, and a top surface 12 facing the bottom surface 11, for example. The bottom surface 11 includes a heat transfer surface 11B that comes in contact with a heat-generating section of the IC chip with no adhesive and a bonding surface 11A that comes in contact with an area other than the heat-generating section through an adhesive PA.

Typically, the temperature of the heat in the IC chip becomes greatest in the center section thereof, and this section becomes a heat-generating section. Therefore, by configuring the bottom surface 11 in the manner described above, it is possible to allow more heat to be dissipated from this heat-generating section, which is most effective in releasing heat from the IC chip. Further, in order to firmly bond the heat dissipation sheet 1 to the IC chip through the periphery or other surface areas where the temperature of generated heat is relatively low, the heat dissipation sheet 1 has the bonding surface 11A in the periphery of the bottom surface of the heat dissipation sheet, which comes in contact with an area other than the heat-generating section.

With this configuration, the heat dissipation sheet 1 is reliably bonded to the IC chip through the bonding surface 11A having the adhesive PA applied thereon, and therefore, the heat dissipation sheet 1 does not easily fall off. In addition, the heat transfer surface 11B having no adhesive applied thereon comes in contact with the heat-generating section in the heat dissipation sheet 1, and therefore, heat is dissipated sufficiently. As a result, a heat dissipation structure of the electronic device that can increase reliability of the electronic device can be achieved.

Typically, an adhesive has lower heat conductivity than that of a heat dissipation sheet, and therefore, a surface having an adhesive applied thereon tends to have a heat resistance. However, because the heat dissipation sheet itself has a small adhesive strength, without the adhesive, the heat dissipation sheet may fall off when the heat dissipation sheet is attached to the IC chip. Therefore, in this embodiment, the heat dissipation sheet is configured such that the heat transfer surface 11B having no adhesive applied thereon comes in contact with the center of the IC chip, which is the heat-generating section, and the bonding surface 11A having an adhesive applied thereon is provided in the periphery region surrounding the center of the bottom surface, i.e., a region where the heat dissipation characteristic has no significance, thereby improving the adhesive strength.

When the heat dissipation sheet 1 is attached to the IC chip 3 by pressing the bottom surface 11, which has the bonding surface 11A on the periphery thereof, on the periphery of the IC chip 3, as shown in a schematic cross-sectional view in FIG. 2B, the heat dissipation sheet 1 is bonded to the periphery of the IC chip 3 that is mounted on the substrate 2 through the bonding surface 11A having the adhesive PA applied thereon. According to this embodiment, as described above, the heat dissipation sheet 1 can be bonded to the IC chip 3 in a proper position.

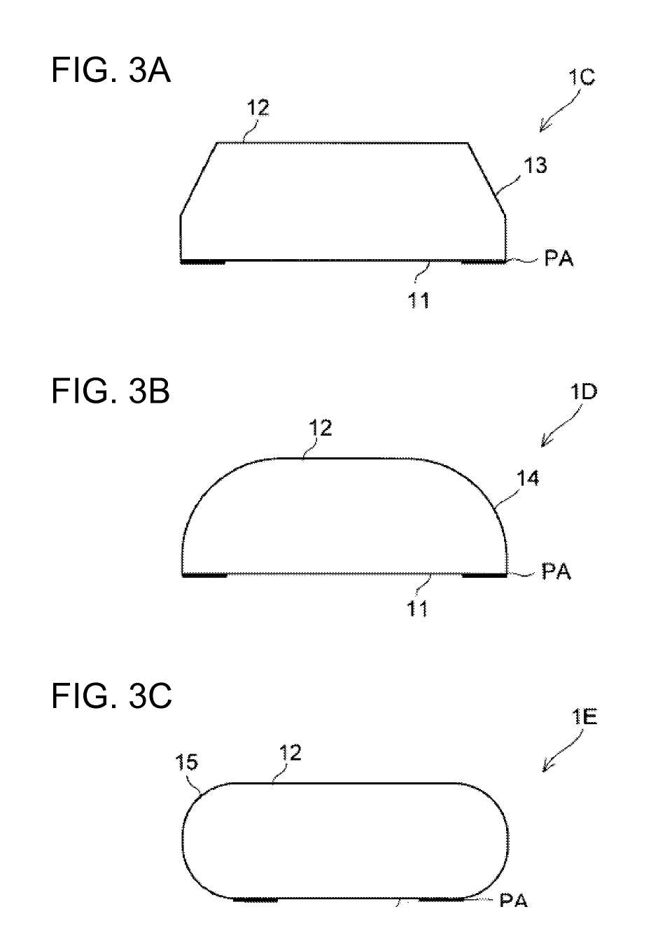

Next, heat dissipation sheets that are configured so as to be even less likely to fall off will be described with reference to FIGS. 3A to 3C.

A heat dissipation sheet 1C shown in FIG. 3A has tapered corners on a top surface 12 facing a bottom surface 11 of the heat dissipation sheet. With this configuration in which corners 13 are tapered, it becomes difficult for the heat dissipation sheet 1C to fall off upon being attached to the IC chip because of the tapered corners on the top surface of the heat dissipation sheet 1C that is to be bonded to the IC chip. Therefore, it becomes possible to reliably attach the heat dissipation sheet 1C to the IC chip.

A heat dissipation sheet 1D shown in FIG. 3B has corners rounded in a circular arc shape on a top surface 12 facing a bottom surface 11 of the heat dissipation sheet. With this configuration in which corners 14 are in a circular-arc shape, it becomes difficult for the heat dissipation sheet 1D to fall off upon being attached to the IC chip because of the circular arc shaped corners on the top surface of the heat dissipation sheet 1D that is to be bonded to the IC chip. Therefore, it becomes possible to reliably attach the heat dissipation sheet 1D to the IC chip.

A heat dissipation sheet 1E shown in FIG. 3C has a flattened shape 15 having rounded side surfaces between a bottom surface 11 and a top surface 12 facing the bottom surface 11. With this configuration, the corners on the top surface of the heat dissipation sheet 1E to be bonded to the IC chip are rounded. This makes it difficult for the heat dissipation sheet 1E to fall off upon being attached to the IC chip. Therefore, it becomes possible to reliably attach the heat dissipation sheet 1E to the IC chip.

In any of the above configurations, it is preferable that the bottom surface 11 have the heat transfer surface 11B, which comes in contact with the heat-generating section of the IC chip without an adhesive, and the bonding surface 11A, which comes in contact with the area other than the heat-generating section with the adhesive PA.

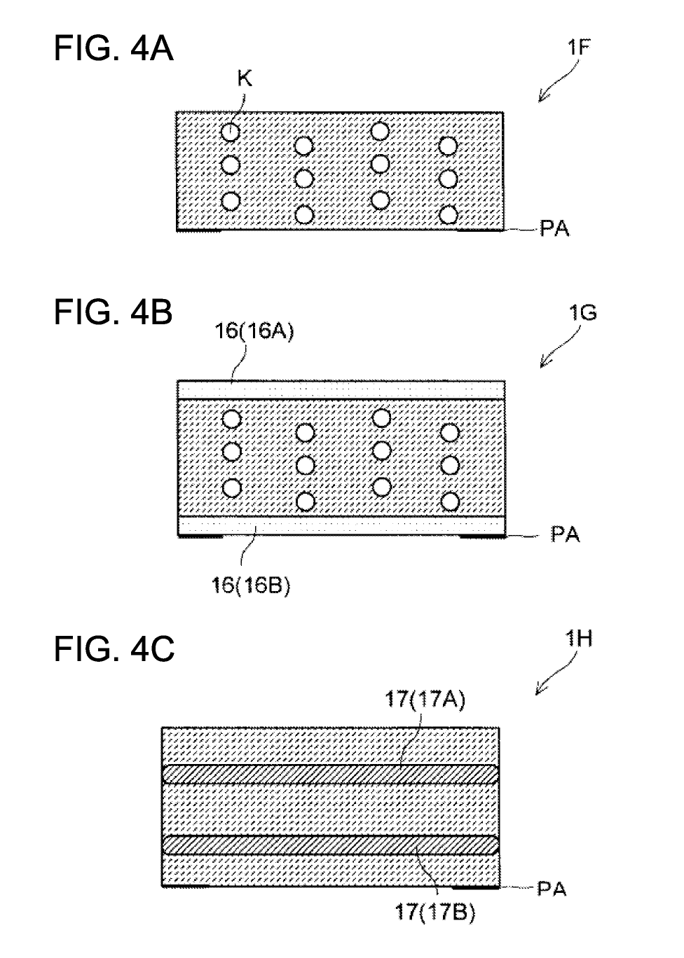

The thicker the heat dissipation sheet is, the worse the heat conductivity becomes. Therefore, it may not be possible to achieve sufficient heat dissipation only with the above-mentioned configuration in which the bonding surface 11A is provided in an area other than the heat-generating section. To address this issue, heat dissipation structures that can dissipate heat sufficiently even when a heat dissipation sheet is made thick will be described with reference to FIGS. 4A to 4C.

A heat dissipation sheet 1F shown in FIG. 4A has particulate heat-conducting additive K having heat conductivity mixed therein. With this configuration, even if the heat dissipation sheet 1F is made thick, heat conductivity in a thickness direction is ensured. Therefore, heat in the IC chip can be reliably dissipated.

For the heat-conducting additive K, metal particles such as copper particles are used, for example. With this configuration, the heat dissipation sheet that has the metal particles with high heat conductivity mixed therein is disposed. This way, the heat conductivity of the heat dissipation sheet in a thickness direction is not lowered, and heat in the IC chip can be reliably dissipated. Therefore, heat is dissipated sufficiently, and reliability of the electronic device can be increased.

In a case where the heat-conducting additive is required to have high heat conductivity, but not to conduct electricity, i.e., the heat-conducting additive is required to be nonconductors, metal particles covered by insulating films can be used. Alternatively, aluminum metal particles that are alumited may be used, or the particulate heat-conducting additive K made of nonconductors having heat conductivity may be used.

Further, as shown in a heat dissipation sheet 1G shown in FIG. 4B, it is preferable that film members 16 (16A and 16B) made of nonconductors having heat conductivity are provided on one or both of the bottom and top surfaces of the heat dissipation sheet, i.e., at least one of the surfaces. With this configuration, even if the heat-conducting additive K to be mixed in have electrical conductivity, it becomes possible to prevent unintended electrical conduction in the IC chip.

The film members 16 (16A and 16B) may be thin resin films having heat conductivity or layers formed by applying and curing an adhesive having heat conductivity.

A heat dissipation sheet 1H shown in FIG. 4C has heat-conducting auxiliary layers 17 (17A and 17B) having heat conductivity are interposed therein. With this configuration, heat conductivity of the heat dissipation sheet in a thickness direction is prevented from being decreased, and therefore, it becomes possible to immediately dissipate heat from the IC chip. This way, the heat dissipation sheet 1H having the heat-conducting auxiliary layers 17 (17A and 17B) with heat conductivity interposed therein can maintain good heat conductivity and can reliably dissipate heat from the IC ship. Therefore, heat is dissipated sufficiently, and reliability of the electronic device can be increased.

The heat-conducting auxiliary layers 17 are formed by placing material pieces having high heat conductivity, such as metal pieces and heat-conducting resins, between heat dissipation sheet materials made of silicon rubber or acrylic rubber. The heat-conducting auxiliary layers 17 may be film-like layers, thin plate-like layers, or other layers in any shape. There is no special limitation on a number of layers being interposed and a density of interposed layers as long as the heat dissipation sheet exhibits desired heat conductivity in a thickness direction of the heat dissipation sheet.

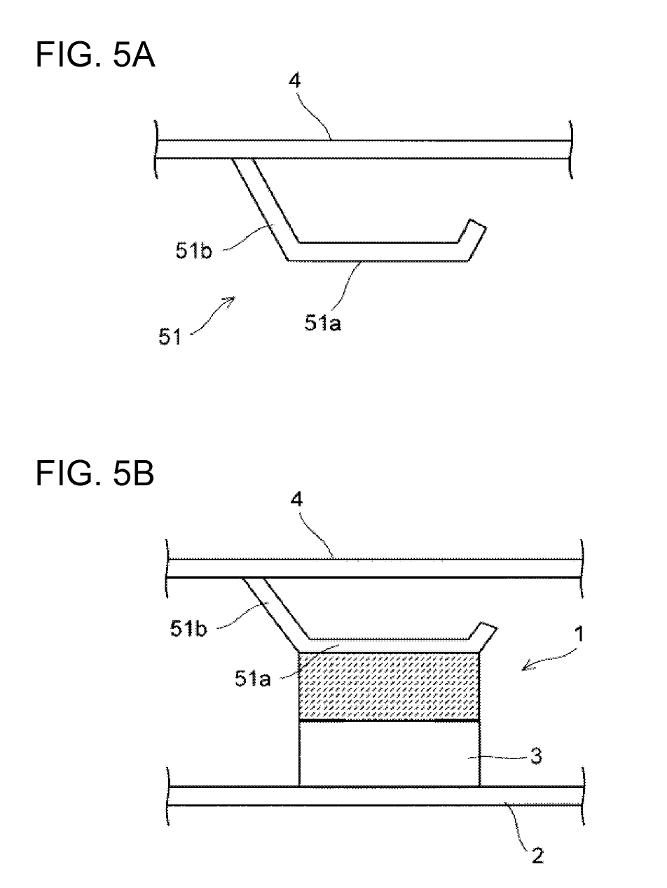

It becomes possible to have the heat dissipation sheet come in contact with the IC chip even more reliably by using a chip pressing member provided on the cover member. The chip pressing member in an embodiment of a modification example will be described with reference to FIGS. 5A and 5B.

The chip pressing member shown in FIG. 5A is an elastic pressing member 51 made of an elastic piece portion 51b and a contact piece portion 51a. One end of the elastic piece portion 51b is fixed to the cover member 4, and the elastic piece portion 51b is elastically movable in a direction toward or away from the cover member. The contact piece portion 51a is connected to the other end of the elastic piece portion 51b, coming in contact with and pressing the heat dissipation sheet.

FIG. 5B shows a state in which the heat dissipation sheet 1 is actually disposed on the IC chip 3 that is mounted on the substrate 2, using the elastic pressing member 51.

As shown in FIG. 5B, the heat dissipation sheet 1 is pressed on the IC chip 3 by the contact piece portion 51a and reliably comes in contact with a top surface of the IC chip 3. At this time, the elastic piece portion 51b is elastically deformed, and the contact piece portion 51a is given an elastic momentum toward the IC chip 3 and toward the top surface of the heat dissipation sheet 1A.

With this configuration, even if variation in a gap between the IC chip 3 and the cover member 4 is generated, the heat dissipation sheet 1 can come in contact with the IC chip 3 and with the cover member 4 with appropriate pressure. Therefore, it is possible to achieve a heat dissipation structure of an electronic device that allows heat to be dissipated sufficiently and that can improve reliability of the electronic device.

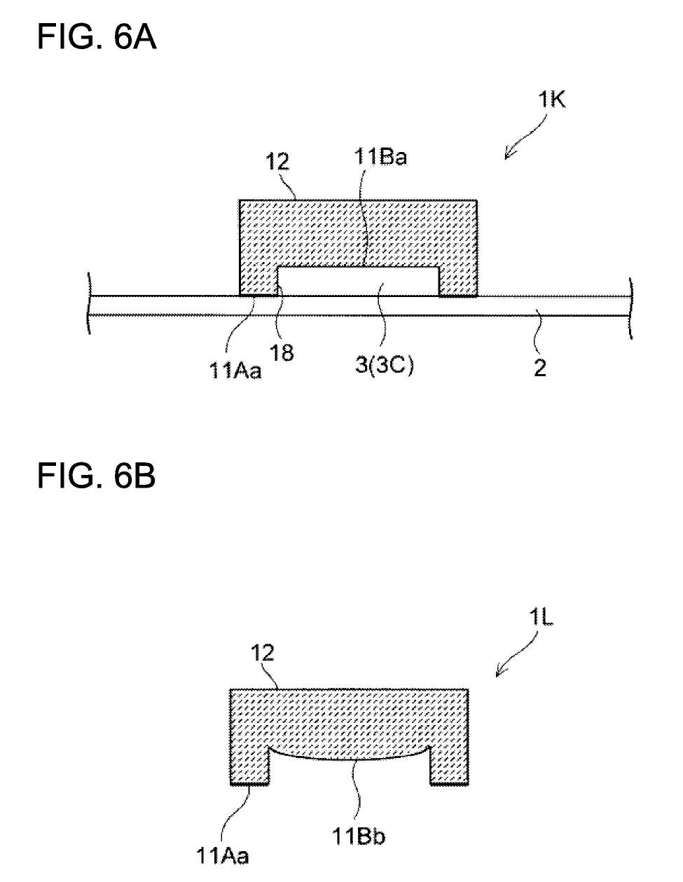

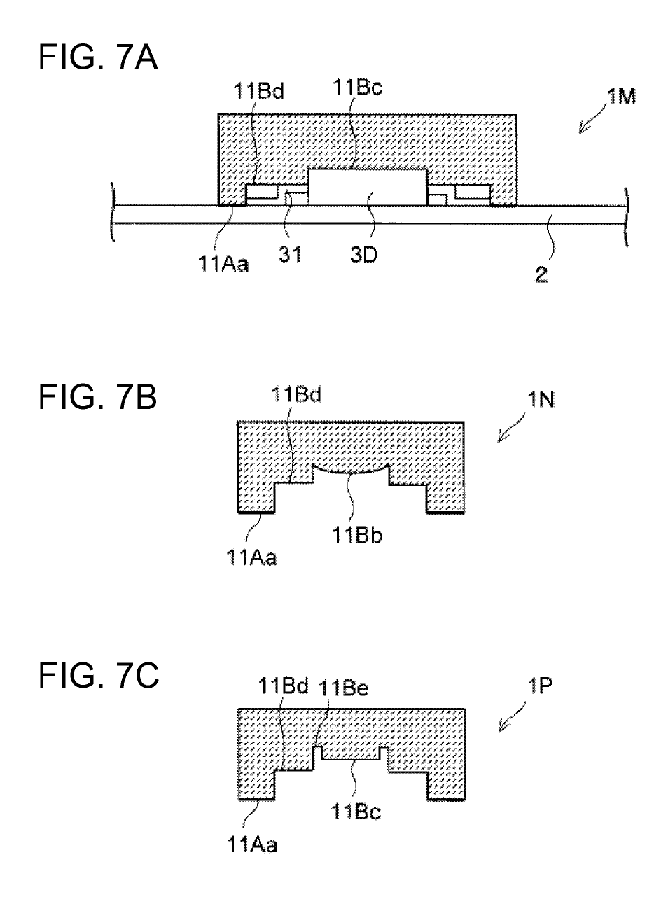

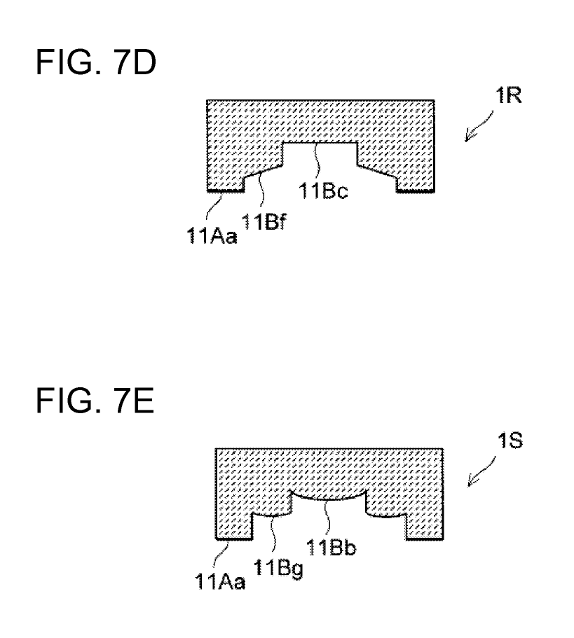

The heat dissipation sheet 1 may have a recessed engaging section in the bottom surface so as to engage the IC chip 3. When a surface surrounding the recessed engaging section in the bottom surface is used as a bonding surface, the heat dissipation sheet 1 can be reliably bonded to the substrate having the IC chip 3 mounted thereon. Embodiments of the heat dissipation sheets having this recessed engaging section will be described with reference to FIGS. 6A, 6B, and 7A to 7E.

A heat dissipation sheet 1K in FIG. 6A shows an embodiment in which a recessed engaging section 18 that engages the IC chip 3 (3C) is provided. If the IC chip 3 (3C) is rectangular, the recessed engaging section 18 is also formed to be rectangular.

In the heat dissipation sheet 1K having this configuration, a recessed surface of the recessed engaging section 18 is used as the heat transfer surface 11Ba, and a surface on the bottom surface surrounding the recessed engaging section 18 is used as the bonding surface 11Aa. When the heat dissipation sheet 1K is pressed on the IC chip 3 (3C) mounted on the substrate 2 so as to engage the IC chip 3 (3C), the bonding surface 11Aa having an adhesive applied thereon is bonded to the substrate 2, and the heat transfer surface 11Ba comes in contact with the heat-generating section of the IC chip 3 (3C).

It is preferable to employ this configuration in which the recessed engaging section 18 that engages the IC chip is made in the bottom surface, a recessed surface of the recessed engaging section 18 is used as the heat transfer surface 11Ba that comes in contact with the IC chip, and the surface surrounding the recessed engaging section 18 is used as the bonding surface 11Aa, because the bonding surface 11Aa is bonded to the substrate 2 having the IC chip mounted thereon, and therefore, the heat dissipation sheet can be reliably bonded and fixed to an area other than the heat-generating section of the IC chip. Further, the heat dissipation sheet is pressed on the IC chip by the chip pressing member 5 or the elastic pressing member 51 described above, and therefore, heat is dissipated sufficiently through the heat transfer surface 11Ba that is attached tightly to the heat-generating section of the IC chip.

A heat dissipation sheet 1L in FIG. 6B shows an embodiment in which a heat transfer surface in the recessed engaging section is protruded in a curved shape in the center thereof, forming a protruded heat transfer surface 11Bb. With this configuration, the protruded heat transfer surface 11Bb is protruded in a curved shape. This way, the heat dissipation sheet reliably comes in contact with the center of the IC chip, which is the heat-generating section, regardless of variation made in processing the heat dissipation. Therefore, heat is dissipated sufficiently, and it becomes possible to increase reliability of the electronic device.

As shown in a heat dissipation sheet 1M shown in FIG. 7A, if a recessed engaging section has a center engaging section 11Bc that engages an outer shape of an IC chip 3D and a terminal contact surface 11Bd that comes in contact with electrode terminals 31 protruded from side faces of the IC chip 3D, the heat dissipation sheet 1M can dissipate heat from the IC chip 3D more effectively through the center engaging section 11Bc that comes in contact with the heat-engaging section of the IC chip and through the terminal contact surface 11Bd that comes in contact with the electrode terminals 31, which also generate heat. Therefore, the heat dissipation performance can be further increased.

In this case, the center engaging section 11Bc may be the protruded heat transfer surface 11Bb that is protruded in a curved shape as described above with reference to FIG. 7B, so that the heat dissipation sheet can reliably come in contact with the center of the IC chip, which is the heat-generating section, regardless of manufacturing errors and variation in processes made in the heat dissipation sheet.

It is preferable to employ a configuration that can ensure that the heat dissipation sheet reliably comes in contact with the center of the IC chip and the electrode terminals, which are the heat-generating sections. Examples of such a configuration include the following: in a heat dissipation sheet 1P shown in FIG. 7C, a groove-shaped clearance section 11Be is made in a circumference of the center engaging section 11Bc; in a heat dissipation sheet 1R shown in FIG. 7D, the terminal contact surface is slanted in a tapered shape, forming a slanted terminal contact surface 11Bf; in a heat dissipation sheet 1S shown in FIG. 7E, the terminal contact surface is protruded in a curved shape, forming a protruded terminal contact surface 11Bg.

When the center engaging section has the groove-shaped clearance section 11Be in the circumference thereof, it is possible to prevent the circumference of the center engaging section formed in the heat dissipation sheet from coming in contact with the IC chip first, which would prevent the heat-conducting surface from making contact with the center of the IC chip, i.e., the heat-generating section, thereby making it easier to attach the heat dissipation sheet. This way, the heat dissipation sheet can be reliably attached to the IC chip such that the heat transfer surface of the heat dissipation sheet comes in contact with the heat-generating section of the IC chip. Therefore, heat is dissipated sufficiently, and it becomes possible to increase reliability of the electronic device.

When the terminal contact surface is the protruded terminal contact surface 11Bf or 11Bg that protrudes toward the electrode terminals 31, the terminal contact surface on the heat dissipation sheet can reliably come in contact with the electrode terminals 31, thereby dissipating heat. In each of the heat dissipation sheets 1M to 1S that are respectively provided with the terminal contact surfaces, the surface on the bottom the that surrounds the recessed engaging section having the center engaging section and the terminal contact surface is used as the bonding surface 11Aa.

As described above, heat in the IC chip can be dissipated through the heat dissipation sheet 1 (1K to 1S) attached to the IC chip so as to cover the entire IC chip. The heat dissipation sheets 1M to 1S respectively provided with the terminal contact surfaces can simultaneously dissipate heat from the electrode terminals and from the IC chip efficiently. Therefore, the heat dissipation performance is improved.

In the heat dissipation sheets 1K to 1S, the heat dissipation performance can be further improved by mixing the particulate heat-conducting additive having heat conductivity in the heat dissipation sheet or by providing heat-conducting auxiliary layers having heat conductivity interposed in the heat dissipation sheet.

As described above, according to the present invention, in the heat dissipation structure in which the IC chip to be the heat-generating element is mounted on the substrate, and the heat dissipation sheet is disposed between the cover member and the IC chip so as to dissipate heat, the heat dissipation sheet has the heat transfer surface and the bonding surface on the bottom surface that is the contact surface with the IC chip. The heat transfer surface has no adhesive applied thereon and comes in contact with the heat-generating section of the IC chip. The bonding surface is provided in an area surrounding the heat transfer surface, and comes in contact with the area other than the heat-generating section through an adhesive. This way, the heat dissipation sheet reliably comes in contact with the IC chip by the bonding surface having an adhesive applied thereon, and therefore, the heat dissipation sheet does not fall off easily. Further, heat is dissipated sufficiently through the heat transfer surface having no adhesive. Therefore, it becomes possible to achieve the heat dissipation structure of the electronic device that can increase reliability of the electronic device.

Further, by cutting the corners on the top surface of the heat dissipation sheet in a tapered shape or by rounding the corners in a circular arc shape, it becomes difficult for the heat dissipation sheet to fall off upon attaching the heat dissipation sheet to the IC chip. Therefore, it becomes possible to reliably attach the heat dissipation sheet to the IC chip.

Further, by mixing particulate heat-conducting additive having heat conductivity in the heat dissipation sheet, or by providing heat-conducting auxiliary layers having heat conductivity interposed in the heat dissipation sheet, a heat resistance in a thickness direction is reduced. Therefore, even if the heat dissipation sheet is made thick, it becomes possible to dissipate heat sufficiently.

### INDUSTRIAL APPLICABILITY

A heat dissipation structure of an electronic device according to the present invention can be suitably used for an electronic device that is required to reliably dissipate heat generated in IC chips.

### DESCRIPTION OF REFERENCE CHARACTERS

1 (1A to 1S) heat dissipation sheet
2 substrate
3 IC chip
31 electrode terminal
4 cover member
5 (5A to 5D) chip pressing member
51 elastic pressing member
11 bottom surface
11A bonding surface
11B heat transfer surface
11Bb recessed heat transfer surface
11Bc center engaging surface
11Bd terminal contact surface
11Be clearance section
11Bf, 11Bg protruded terminal contact surface
12 top surface
13 tapered corner
14 circular arc-shaped corner
15 flattened shape
16 (16A, 16B) film member
17 (17A, 17B) heat-conducting auxiliary layer
18 recessed engaging section
K heat-conducting additive
PA adhesive

1. A heat dissipation structure of an electronic device, comprising: an IC chip; a substrate having the IC chip mounted thereon; a cover member having a heat dissipation characteristic and covering a mounting surface of the substrate; and a heat dissipation sheet disposed between the IC chip and the cover member, the heat dissipation structure dissipating heat from the IC chip,
wherein the heat dissipation sheet has, on a bottom surface thereof that corresponds to a contact surface with the IC chip, a heat transfer surface that comes in contact with a heat-generating section of the IC chip and that has no adhesive applied thereon, and a bonding surface that comes in contact with an area other than the heat-generating section and that has an adhesive applied thereon.

2. The heat dissipation structure of the electronic device according to claim 1, wherein a recessed engaging section that engages the IC chip is provided in the bottom surface, a recessed surface of the recessed engaging section is used as the heat transfer surface that comes in contact with the IC chip, and a surface surrounding the recessed engaging section on the bottom surface is used as the bonding surface.

3. The heat dissipation structure of the electronic device according to claim 1, wherein a top surface of the heat dissipation sheet facing the bottom surface has corners cut in a tapered shape.

4. The heat dissipation structure of the electronic device according to claim 1, wherein a top surface of the heat dissipation sheet facing the bottom surface has corners rounded in a circular arc shape.

5. The heat dissipation structure of the electronic device according to claim 1, wherein the heat dissipation sheet is formed in a flattened shape having rounded side surfaces between the bottom surface and a top surface facing the bottom surface.

6. The heat dissipation structure of the electronic device according to claim 1, wherein the heat dissipation sheet has particulate heat-conducting additive having heat conductivity mixed therein.

7. The heat dissipation structure of the electronic device according to claim 6, wherein the heat dissipation sheet has a film member that has heat conductivity and that is made of nonconductors disposed on at least one of the bottom surface or a top surface.

8. The heat dissipation structure of the electronic device according to claim 6, wherein the heat-conducting additive is metal particles.

9. The heat dissipation structure of the electronic device according to claim 1, wherein the heat dissipation sheet has a heat-conducting auxiliary layer having heat conductivity interposed therein.

10. The heat dissipation structure of the electronic device according to claim 2, wherein the heat transfer surface in the recessed engaging section is a protruded heat transfer surface having a center thereof protruded in a curved shape.

11. The heat dissipation structure of the electronic device according to claim 2, wherein the recessed engaging section has a center engaging section that engages an outer shape of the IC chip and a terminal contact surface that comes in contact with an electrode terminal, which is provided on a side face of the IC chip.

12. The heat dissipation structure of the electronic device according to claim 11, wherein the center engaging section has a clearance section in a circumference thereof.

13. The heat dissipation structure of the electronic device according to claim 11, wherein the terminal contact surface is a protruded terminal contact surface that is protruded toward the electrode terminal.
